(19) United States
(12) Patent Application Publication
(10) Pub. No.: US 2008/0107222 A1
(43) Pub. Date: May 8, 2008

(54) System and method for signal phase correction

(75) Inventors: Joshua Douglas Talbert, Garland, TX (US); Darrel Ray Judd, Rockwall, TX (US); John Andrew Adams, Greenville, TX (US)

Correspondence Address: HOVEY WILLIAMS LLP, 10801 Mastin Blvd., Suite 1000, Overland Park, KS, 66210, US

(73) Assignee: L3 COMMUNICATIONS INTEGRATED SYSTEMS, L.P., Greenville, TX (US)

(21) Appl. No.: 11/556,722

(22) Filed: Nov. 6, 2006

(51) Int. Cl. H03D 3/24

(52) U.S. Cl. 375/375; 455/42

(57) ABSTRACT

A method and apparatus for correcting a phase of a phase-modulated signal for blind demodulation. The method and apparatus generally include the creation of a plurality of angle bins, wherein each constellation point of the phase-modulated signal is assigned to an angle bin, depending on its phase angle. A histogram is formed of the angle bins and cross correlated with a template signal model histogram. The maximum value of the cross correlation determines a correction angle by which the phase angle of all the phase-modulated constellation points is multiplied.

### BACKGROUND OF THE INVENTION

1. Field of the Invention

The present invention relates to correcting the phase of a phase-modulated signal. More particularly, the invention relates to a method and apparatus for correcting the phase of a phase modulated signal for blind demodulation, wherein the signal corresponds to constellation points plotted on a complex plane of a constellation diagram.

2. Description of the Related Art

Communication of data is often accomplished by modulating a carrier signal. The carrier signal is a periodic waveform, typically sinusoidal in nature. The data can be any information that needs to be transmitted, such as audio, video, or electronically generated data. Modulation of a carrier wave generally involves modifying one of the parameters of the wave. These parameters include the amplitude of the wave, its frequency, and its phase. Modulation of the phase typically involves a time delay of the wave as compared with an unmodulated carrier wave. Phase modulation techniques include quadrature amplitude modulation (QAM) and phase shift keying (PSK).

When the phase of the carrier wave is modulated to encode data for transmission, the phase of the unmodulated carrier wave is obviously known. However, when the data is received and demodulation is required, the phase of the original carrier wave might not be known. This is referred to as blind demodulation. During the blind demodulation process, the problem is that a phase offset is typically introduced. A method is required to eliminate the offset and correct the phase of the phase-modulated received signal.

### SUMMARY OF THE INVENTION

The present invention solves the above-described problem and provides a distinct advance in the art of phase correction of a phase-modulated signal for blind demodulation. More particularly, the invention provides a method and apparatus for correcting the phase of a phase-modulated signal for blind demodulation, wherein the signal corresponds to constellation points plotted on a complex plane of a constellation diagram.

One embodiment of the invention provides a method which generally begins with dividing the complex plane into a plurality of equally-spaced angle bins. The phase angle of each constellation point and the angle bin corresponding to the phase angle of each constellation point are then determined. A histogram of the angle bins for the phase-modulated signal is created. The corresponding template signal model histogram is identified, and a cross correlation of the two histograms is calculated. The maximum value of the cross correlation and in turn, the index of the maximum value are determined. From the maximum value index, a correction angle is derived. The phase of the phase-modulated signal is corrected by multiplying the phase angle of all the constellation points by the correction angle.

In another embodiment, the present invention provides a computer program for correcting the phase of a phase-modulated signal. The computer program is stored on a computer-readable medium for operating a processor or other computing device and generally includes a code segment operable to divide the complex plane into a plurality of equally-spaced angle bins, a code segment operable to determine the phase angle of each constellation point; a code segment operable to determine the angle bin for each constellation point that corresponds to the phase angle for each constellation point; and a code segment operable to create a phase-modulated signal histogram of the number of points in each angle bin. The computer program also includes a code segment operable to cross correlate the phase-modulated signal histogram with a template signal model histogram; a code segment operable to determine a correction angle from the maximum value of the cross correlation; and a code segment operable to multiply the phase angle of each constellation point by the correction angle.

In another embodiment, the present invention provides an apparatus for correcting the phase of a phase-modulated signal for blind demodulation. The apparatus comprises a memory element and a processor. The memory element is operable to store data corresponding to a plurality of template signal model histograms, and a plurality of phase-modulated signal data points. The processor is operable to divide the complex plane into a plurality of equally-spaced angle bins; determine the phase angle of each constellation point; determine the angle bin for each constellation point that corresponds to the phase angle for each constellation point; and create a phase-modulated signal histogram of the number of points in each angle bin. The processor is also operable to cross correlate the phase-modulated signal histogram with a corresponding template signal model histogram; determine a correction angle from the maximum value of the cross correlation; and multiply the phase angle of each constellation point by the correction angle.

Other aspects and advantages of the present invention will be apparent from the following detailed description of the preferred embodiments and the accompanying drawing figures.

### BRIEF DESCRIPTION OF THE DRAWING FIGURES

A preferred embodiment of the present invention is described in detail below with reference to the attached drawing figures, wherein:

FIG. 1 is a block diagram of some of the elements operable to be utilized by various embodiments of the present invention;

FIG. 2 is a constellation diagram illustrating the constellation points of an implementation of 16QAM;

FIG. 3 is a constellation diagram with a scatter plot of the constellation points with incorrect phase from a phase-modulated signal;

FIG. 4A and FIG. 4B show a flow chart showing some of the steps operable to be performed by various embodiments of the present invention;

FIG. 5 is a constellation diagram depicting a plurality of equally-spaced angle bins;

FIG. 6 is a constellation diagram with the angle bins and the scatter plot of the constellation points depicting the determination of the correct angle bin for each constellation point;

FIG. 7 illustrates a comparison between the phase-modulated signal histogram and the template signal model histogram;

FIG. 8 is a plot of the cross correlation of the phase-modulated signal histogram and the template signal model histogram; and

FIG. 9 is a constellation diagram depicting the constellation points of the phase-modulated signal before phase correction and after phase correction.

The drawing figures do not limit the present invention to the specific embodiments disclosed and described herein. The drawings are not necessarily to scale, emphasis instead being placed upon clearly illustrating the principles of the invention.

### DETAILED DESCRIPTION OF THE PREFERRED EMBODIMENTS

The following detailed description of the invention references the accompanying drawings that illustrate specific embodiments in which the invention can be practiced. The embodiments are intended to describe aspects of the invention in sufficient detail to enable those skilled in the art to practice the invention. Other embodiments can be utilized and changes can be made without departing from the scope of the present invention. The following detailed description is, therefore, not to be taken in a limiting sense. The scope of the present invention is defined only by the appended claims, along with the full scope of equivalents to which such claims are entitled.

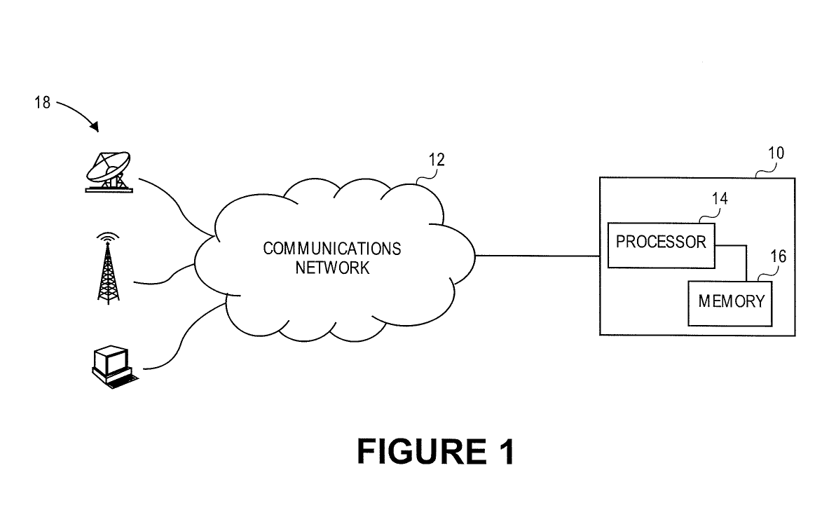

Methods consistent with the present teachings are especially well-suited for implementation by a computing element 10, as illustrated in FIG. 1. The computing element 10 may be a part of or coupled with a communications network 12 that enables various devices to exchange information and data. The computing element 10 may include a processor 14 coupled with a memory 16 to perform the various functions described herein. As should be appreciated, the processor 14 and memory 16 may be integral or discrete and comprise various generally conventional devices, such as microcontrollers, microprocessors, programmable logic devices, desktop computers, servers, portable computing devices, etc.

Additionally, the computing element 10 may include additional devices, such as a display for indicating processed information or additional processing and memory elements. Further, the computing element 10 may comprise a plurality of computing elements or a network of computing elements such that one or more portions of the invention may be implemented utilizing a first computing element and one or more other portions of the invention may be implemented utilizing a second computing element.

The present invention can be implemented in hardware, software, firmware, or combinations thereof. In a preferred embodiment, however, the invention is implemented with a computer program. The computer program and equipment described herein are merely examples of a program and equipment that may be used to implement the present invention and may be replaced with other software and computer equipment without departing from the scope of the present teachings. It will also be appreciated that the principles of the present invention are useful independently of a particular implementation, and that one or more of the steps described herein may be implemented without the assistance of the computing element 10.

Computer programs consistent with the present teachings can be stored in or on a computer-readable medium residing on or accessible by the computing element 10, such as the memory 16, for instructing the computing element 10 to implement the method of the present invention as described herein. The computer program preferably comprises an ordered listing of executable instructions for implementing logical functions in the computing element 10 and other computing devices coupled with the computing element 10. The computer program can be embodied in any computer-readable medium for use by or in connection with an instruction execution system, apparatus, or device, such as a computer-based system, processor-containing system, or other system that can fetch the instructions from the instruction execution system, apparatus, or device, and execute the instructions.

The ordered listing of executable instructions comprising the computer program of the present invention will hereinafter be referred to simply as “the program” or “the computer program.” It will be understood by persons of ordinary skill in the art that the program may comprise a single list of executable instructions or two or more separate lists, and may be stored on a single computer-readable medium or multiple distinct media.

In the context of this application, a “computer-readable medium”, including the memory 16, can be any means that can contain, store, communicate, propagate or transport the program for use by or in connection with the instruction execution system, apparatus, or device. The computer-readable medium can be, for example, but not limited to, an electronic, magnetic, optical, electromagnetic, infrared, or semi-conductor system, apparatus, device, or propagation medium. More specific, although not inclusive, examples of the computer-readable medium would include the following: an electrical connection having one or more wires, a portable computer diskette, a random access memory (RAM), a read-only memory (ROM), an erasable, programmable, read-only memory (EPROM or Flash memory), an optical fiber, and a portable compact disc (CD) or a digital video disc (DVD). The computer-readable medium could even be paper or another suitable medium upon which the program is printed, as the program can be electronically captured, via for instance, optical scanning of the paper or other medium, then compiled, interpreted, or otherwise processed in a suitable manner, if necessary, and then stored in a computer memory.

As shown in FIG. 1, the computing element 10 is preferably directly or indirectly coupled with one or more receiving elements 18 to enable function of the present invention as described herein. It should be appreciated the computing element 10 and the receiving elements 18 may be integral such as where one or more of the receiving elements 18 are operable to independently perform signal tracking as described herein. Thus, the computing element 10 and receiving elements 18 need not necessarily be coupled through the communications network 12 with other devices or collector elements to enable operation of the present invention.

The receiving elements 18 may include any devices or elements that are operable to detect and/or otherwise receive an emitted electromagnetic signal. Thus, the collector elements 18 may include stationary and non-stationary antennas, unidirectional and omni-directional antennas, electrical elements operable to relay a signal, etc. In various embodiments the collector elements 18 may comprise a plurality of communication towers, such as cellular-phone towers, associated via the communications network 12. Thus, the present invention is not limited to the utilization of only one type or configuration of receiving elements 18.

Data communication using a carrier signal involves modifying or modulating some aspect of that signal. The carrier signal is a periodic waveform that is usually sinusoidal in nature. Parameters of the carrier wave that can be modified include the amplitude of the wave, its frequency, and its phase. The phase of the waveform can be thought of as its position in time. Modulation of the phase can be regarded as delaying the waveform in time. Techniques that modulate the phase of the carrier wave include quadrature amplitude modulation (QAM) and phase shift keying (PSK).

QAM involves the modulation of two sinusoidal carrier waves that are 90° out of phase with each other, such as a sine wave and a cosine wave. In simple terms, the data to communicated is multiplied by both the sine wave and the cosine wave and the results are added to create a wave in which both the phase and the amplitude are modulated.

PSK is similar to QAM, except that the amplitude of the modulated wave is kept constant, so that only the phase of the wave is modulated.

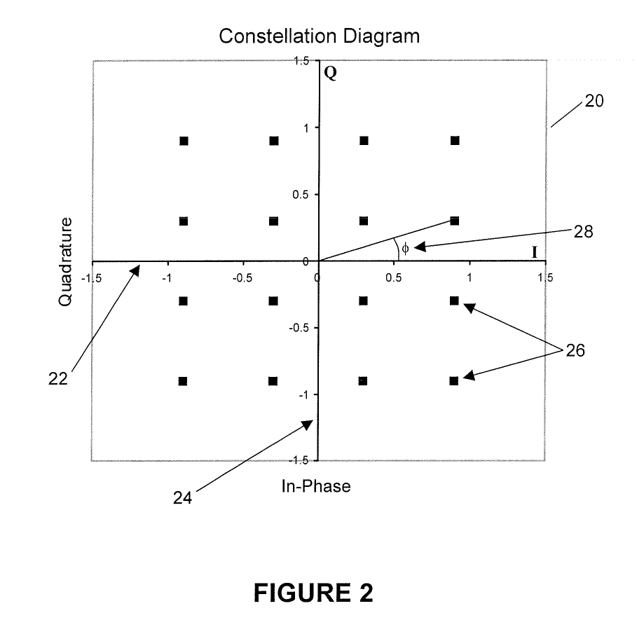

Both QAM and PSK utilize constellation diagrams to represent the modulated carrier waveform. The constellation diagram plots data on a complex plane. FIG. 2 illustrates a constellation diagram 20. The axes of the complex plane are derived from the two carrier waves of the modulation techniques. Thus, the x-axis is the in-phase or I-axis 22, and the y-axis is the quadrature phase or Q-axis 24. Each data point plotted on the constellation diagram is a symbol, or constellation point 26, and represents the amplitude and phase of one period of the modulated waveform.

The constellation diagram 20 of FIG. 2 illustrates an implementation of QAM. QAM is implemented in varying levels of encoding. Each point 26 in the constellation diagram 20 represents a quantity of encoded data or a number of bits. The number of constellation points (#points) in the diagram is generally a power of 2, and is determined by the number of bits (#bits) of encoded data as shown in the equation: #points=2^{#bits}. The particular implementation of QAM is generally denoted by the number of constellation points present in the diagram. Thus, 16QAM is shown in the diagram 20 of FIG. 2. As mentioned above, QAM varies or modulates both the amplitude and the phase of the carrier signal. Illustrated in the constellation diagram 20 of FIG. 2 is a 16QAM implementation with three varying levels of amplitude (measure as a vector from the origin to each point 26) and twelve different phases. The phase angle, φ, 28 is an angle formed with respect to the positive I-axis 22, and its value is determined by Φ=tan⁻¹(Q-value/I-value).

Although modulation of the amplitude has been mentioned in the discussion of QAM for illustrative purposes, embodiments of the present invention relate only to the modulation and more specifically to the demodulation of the phase of a phase-modulated signal.

When the carrier waveforms are modulated for transmission of data, the phase of the constellation points is known relative to the 0° phase reference point. When the signal is received and ready for demodulation, its phase, or position in time, relative to the original carrier waves might not be known. Thus, the demodulation has to be done “blindly” with respect to the absolute phase of the signal.

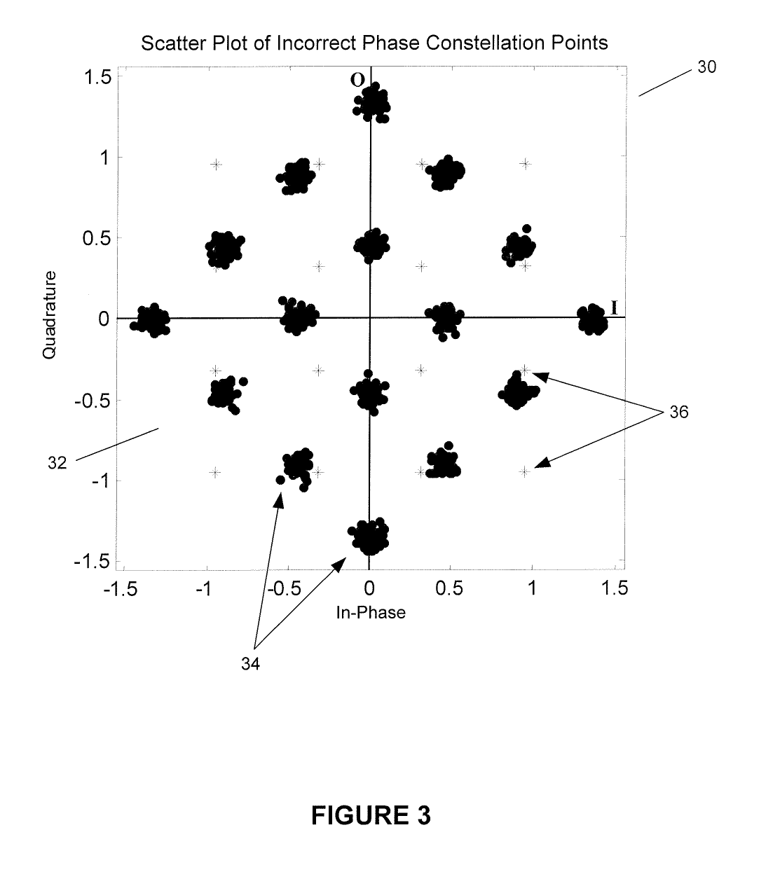

FIG. 3 shows a constellation diagram 30, that includes a scatter plot 32 of the constellation points 34 of a blindly demodulated carrier signal in a 16QAM implementation. 16QAM is used as an example to illustrate the embodiments of the present invention. However, embodiments of the present invention could be applied to other levels of QAM, as well as various levels of PSK, and generally any phase-modulated data transmission scheme.

The scatter plot 32 is generally a plotting of all the occurrences of an event. In this case, the scatter plot represents all the demodulated constellation points 34 in a received data stream. It can be seen that not all the points in a cluster line up on the same spot as would be expected in the ideal case shown in the constellation diagram 20 of FIG. 2. This is the result of the non-ideal situation of real-world data transmission, and won't be discussed any further in detail.

The constellation diagram 30 of FIG. 3 also illustrates the ideal point placement 36 of the template 16QAM implementation. These are the points where the received constellation points 34 should be located. But since the reference point of the phase is not known, the plotted points 34 show a phase offset and thus, the need for phase correction.

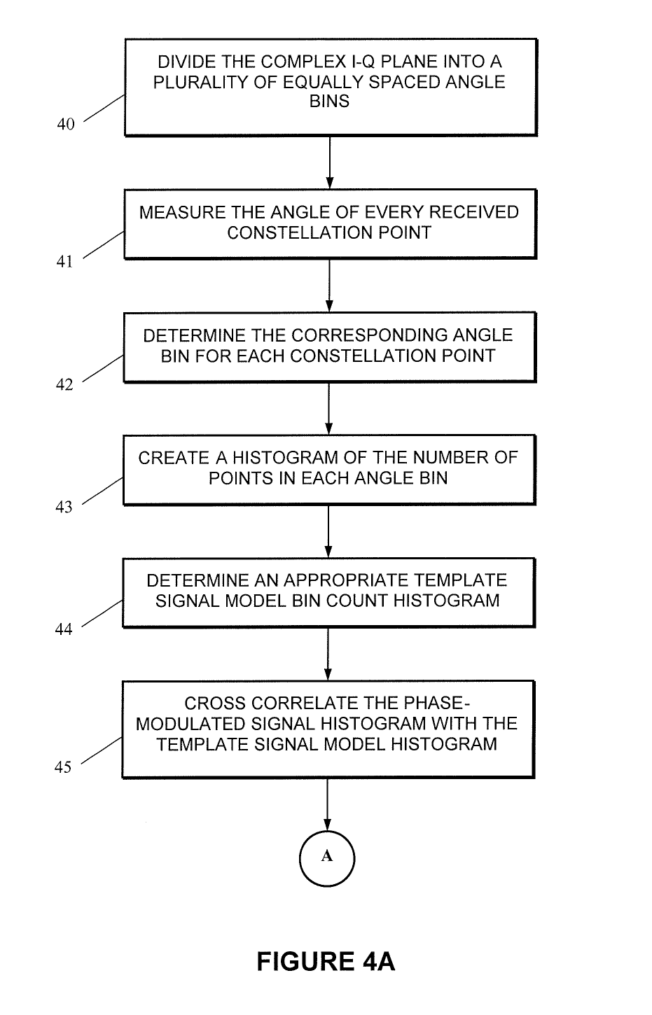

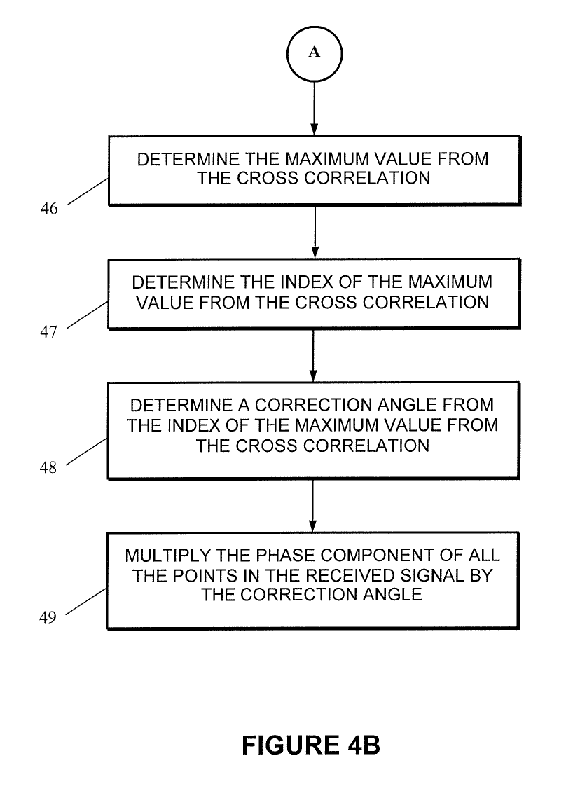

FIG. 4A and FIG. 4B show a flowchart of some of the steps of the method to be performed in various embodiments of the current invention. In order to perform the method, a plurality of constellation points has to be received and captured. In preferred embodiments, 16,384 points are utilized in the method of the present invention. The number of points utilized in the method can vary and may depend on factors such as speed of calculation, amount of data storage space, and data bit error rates.

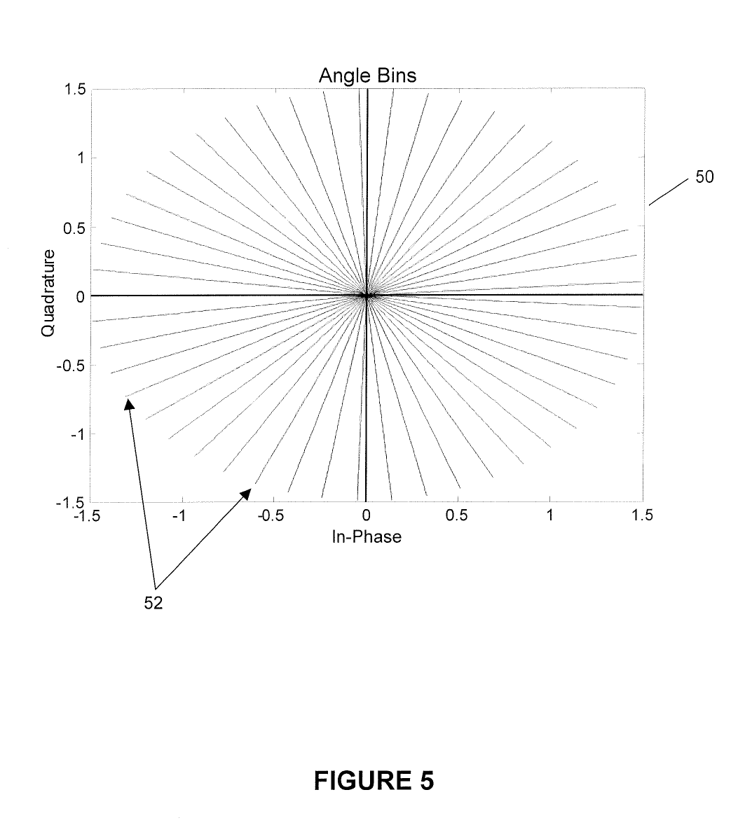

The method generally begins at step 40 with dividing the complex plane of a constellation diagram into a plurality of equally-spaced angle bins, as depicted in the constellation diagram 50 and angle bins 52 of FIG. 5. In one embodiment, there are 512 angle bins created at step 40. The number of angle bins depends generally on the number of constellation points, which is related to the level of QAM or other modulation technique. Typically, the greater the number of constellation points, the greater the number of angle bins.

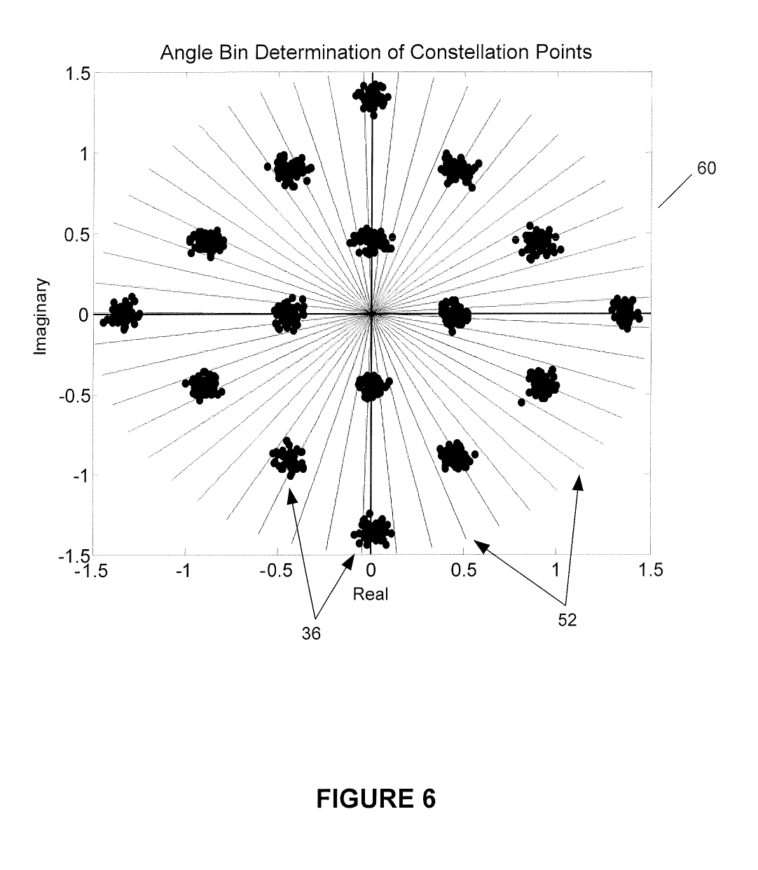

The method continues at step 41 with measuring the phase angle of every received constellation point, as depicted in the constellation diagram 60 of FIG. 6, which shows received constellation points 34 and angle bins 52. The next step 42 is to determine the corresponding angle bin 52 for each constellation point 34.

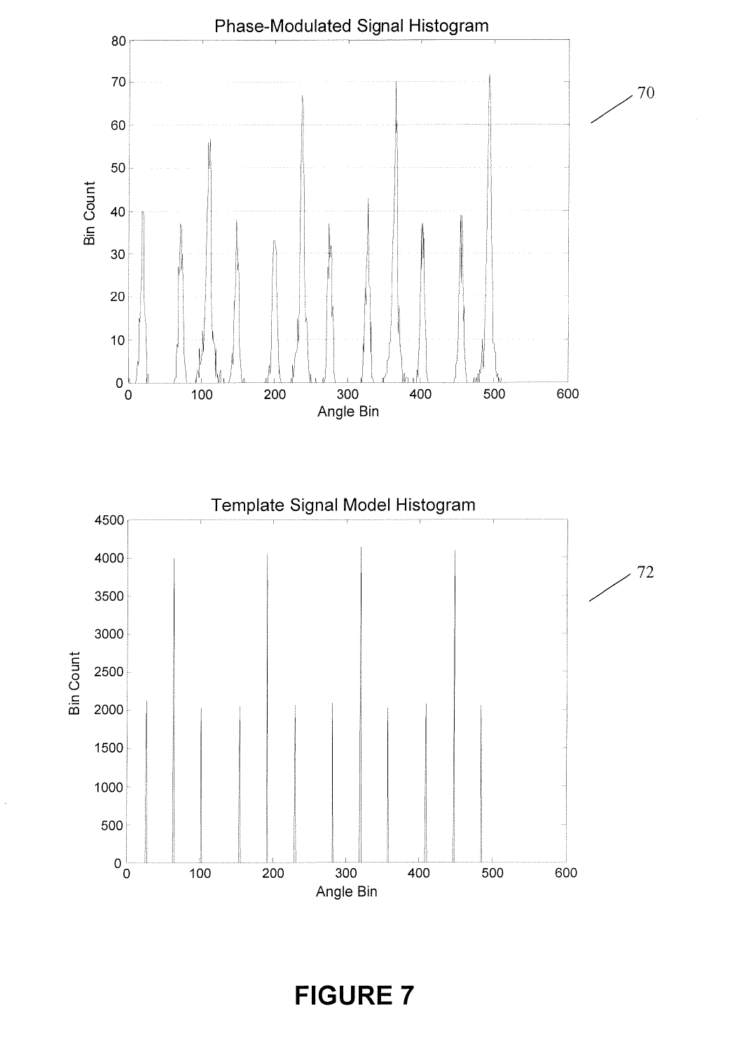

A histogram of the number of constellation points in each angle bin is created in step 43. This is shown in the histogram 70 of FIG. 7. As can be seen in histogram 70, there are twelve spikes of data, representing to the twelve phases of the constellation points 34 plotted in FIGS. 3 and 6. The four tallest spikes of data are roughly twice the height of the others and correspond to those phases (in this case, along the I and Q axes) where there are two amplitudes of the modulated carrier wave.

Step 44 is to determine an appropriate template signal model histogram. The histogram should match the type of modulation scheme that is used to modulate the data. In the illustrative example discussed here, a 16QAM histogram should be used. FIG. 7 also shows a histogram 72 of the ideal template signal model. This is a histogram of what the received constellation points 34 of FIG. 3 would look like if they landed on the target points 36, and if they didn't suffer from any non-ideal circumstances of data transmission.

Step 45 is to cross correlate the received phase-modulated signal histogram with the template signal model histogram. The cross correlation is accomplished by taking the discrete time Fourier transform (DFT) of both the histogram of the phase-modulated signal (X_{RX}) and the histogram of the template signal model (X_{TSM}). Next, the DFT of the template signal model histogram is multiplied by the complex conjugate of the DFT of the phase-modulated signal. Finally, the inverse DFT (IDFT) of the product is calculated to complete the cross correlation (x_{CC}). The process is summarized by the following equations:

X_{RX}=DFT(phase-modulated signal histogram) (1)

X_{TSM}=DFT(template signal model histogram) (2)

X_{RX}_{_{—}}_{TSM}=X_{RX}×X_{TSM}* (3)

x_{CC}=IDFT(X_{RX}_{_{—}}_{TSM}) (4)

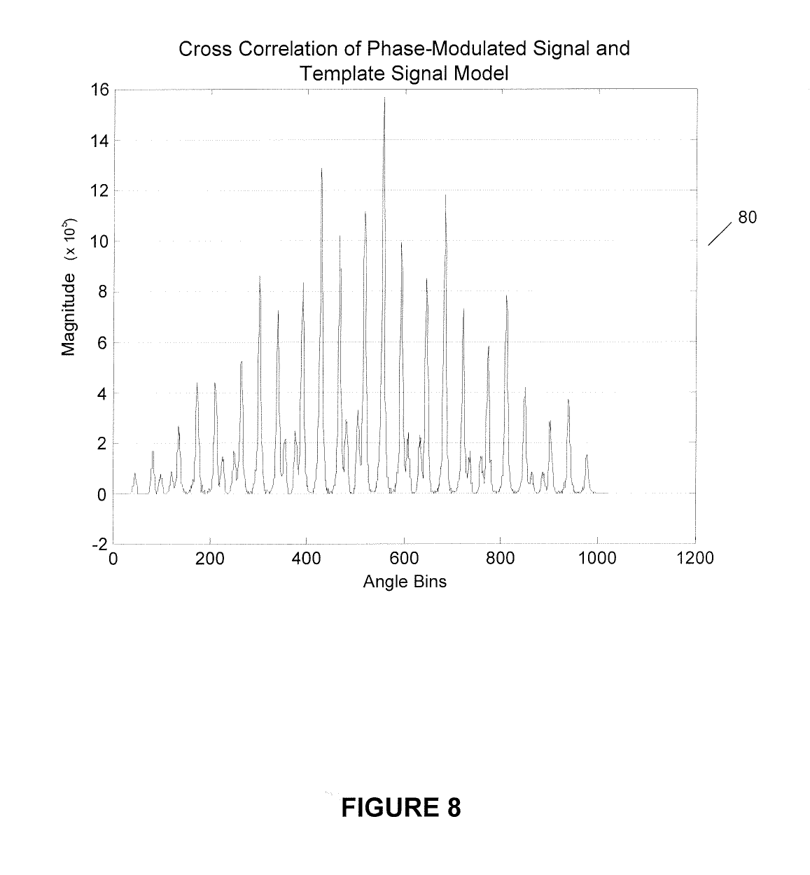

FIG. 8 is a plot of the cross correlation 80 derived by Equations 1-4 from the histograms 70 and 72 of FIG. 7. It can be seen from FIG. 8 that the cross correlation 80 calculation results in 2N-1 indices of angle bins, given that N is the original number of angle bins.

The maximum value of the cross correlation is determined in step 46. Next, the index of the angle bin that has the maximum cross correlation value is determined in step 47. A correction angle is then determined in step 48. The correction angle is determined by the equation:

$$correction\_angle = \frac{( angle\_bin \_index - N + 1 ) \times 2 π}{N} \qquad ( 5 )$$

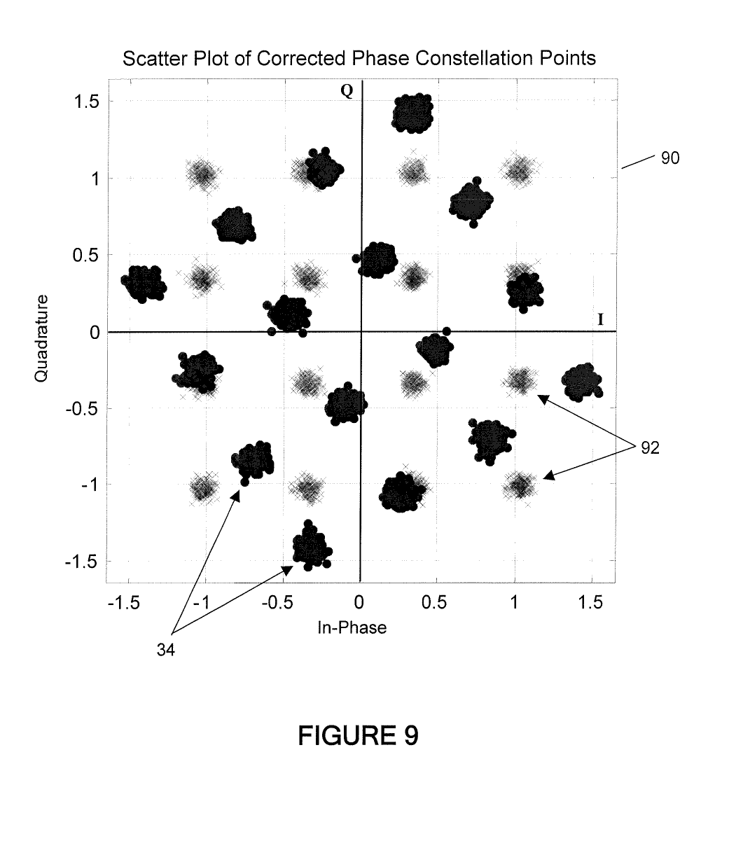

Once the correction angle is calculated, to correct the phase of the received phase-modulated data stream, the phase angles of all the constellation points are multiplied by the correction angle, as indicated in step 49. The results of the phase correction are shown in the scatter plot 90 of FIG. 9. The plot 90 shows the original phase-offset constellation points 34 along with the phase corrected points 92.

Although the invention has been described with reference to the preferred embodiment illustrated in the attached drawing figures, it is noted that equivalents may be employed and substitutions made herein without departing from the scope of the invention as recited in the claims.

Having thus described the preferred embodiment of the invention, what is claimed as new and desired to be protected by Letters Patent includes the following:

1. A method of correcting a phase of a phase-modulated signal for blind demodulation, wherein the signal corresponds to constellation points plotted on a complex plane of a constellation diagram, the method comprising the steps of:
(a) cross correlating a phase-modulated signal histogram with a template signal model histogram;
(b) determining a correction angle from a maximum value of the cross correlation; and
(c) multiplying a phase angle of each constellation point by the correction angle.

2. The method of claim 1, wherein the phase-modulated signal histogram is created with the following steps:
(d) dividing the complex plane into a plurality of equally-spaced angle bins;
(e) determining the phase angle of each constellation point;
(f) determining the angle bin for each constellation point that corresponds to the phase angle for each constellation point; and
(g) developing a histogram of the number of points in each angle bin.

3. The method of claim 2, wherein the phase angle is determined from an I-value and a Q-value relative to the I and Q axes of the complex plane, such that the phase angle=tan⁻¹(Q-value/I-value).

4. The method of claim 1, wherein the cross correlating step further includes the steps of:
(h) performing a discrete time Fourier transform of the phase-modulated signal histogram;
(i) performing a discrete time Fourier transform of the template signal histogram;
(j) multiplying the discrete time Fourier transform of the template signal histogram by a complex conjugate of the discrete time Fourier transform of the phase-modulated signal histogram; and
(k) performing an inverse discrete time Fourier transform of the product of step (j).

5. The method of claim 1, wherein determining the correction angle, given that the number of angle bins=N, includes the steps of:
(l) determining an angle bin index of a maximum cross correlation value; and
(m)
$$calculating the correction angle = \frac{( angle\_bin \_index - N + 1 ) \times 2 π}{N} .$$

6. A method of correcting a phase of a phase-modulated signal for blind demodulation, wherein the signal corresponds to constellation points plotted on a complex plane of a constellation diagram, the method comprising the steps of:
(a) dividing the complex plane into a plurality of equally-spaced angle bins;
(b) determining a phase angle of each constellation point;
(c) determining the angle bin for each constellation point that corresponds to the phase angle for each constellation point;
(d) creating a phase-modulated signal histogram of the number of points in each angle bin;
(e) cross correlating the phase-modulated signal histogram with a template signal model histogram;
(f) determining a correction angle from a maximum value of the cross correlation; and
(g) multiplying the phase angle of each constellation point by the correction angle.

7. The method of claim 6, wherein the cross correlating step further includes the steps of:
(h) performing a discrete time Fourier transform of the phase-modulated signal histogram;
(i) performing a discrete time Fourier transform of the template signal histogram;
(j) multiplying the discrete time Fourier transform of the template signal histogram by a complex conjugate of discrete time Fourier transform of the phase-modulated signal histogram; and
(k) performing an inverse discrete time Fourier transform of the product of step (j).

8. The method of claim 6, wherein the determination of the correction angle, given that the number of angle bins=N, includes the steps of:
(l) determining an angle bin index of a maximum cross correlation value; and
(m)
$$calculating the correction angle = \frac{( angle\_bin \_index - N + 1 ) \times 2 π}{N} .$$

9. The method of claim 6, wherein the phase angle is determined from an I-value and a Q-value relative to the I and Q axes of the complex plane, such that the phase angle=tan⁻¹(Q-value/I-value).

10. A computer program for correcting a phase of a phase-modulated signal for blind demodulation, wherein the signal corresponds to constellation points plotted on a complex plane of a constellation diagram, the computer program stored on a computer-readable medium for operating a processor and comprising:
a code segment operable to cross correlate a phase-modulated signal histogram with a template signal model histogram;
a code segment operable to determine a correction angle from a maximum value of the cross correlation; and
a code segment operable to multiply a phase angle of each constellation point by the correction angle.

11. The computer program of claim 10, further comprising:
a code segment operable to divide the complex plane into a plurality of equally-spaced angle bins;
a code segment operable to determine the phase angle of each constellation point;
a code segment operable to determine the angle bin for each constellation point that corresponds to the phase angle for each constellation point; and
a code segment operable to create a phase-modulated signal histogram of the number of points in each angle bin.

12. The computer program of claim 10, further comprising:
a code segment operable to perform a discrete time Fourier transform of the phase-modulated signal histogram;
a code segment operable to perform a discrete time Fourier transform of the template signal histogram;
a code segment operable to multiply the discrete time Fourier transform of the template signal histogram by the complex conjugate of discrete time Fourier transform of the phase-modulated signal histogram; and
a code segment operable to perform an inverse discrete time Fourier transform of the product of the discrete time Fourier transform of the template signal histogram and the complex conjugate of discrete time Fourier transform of the phase-modulated signal histogram.

13. The computer program of claim 10, further comprising:
a code segment operable to determine an angle bin index of a maximum cross correlation value, wherein there are N angle bins; and
a code segment operable to
$$calculating the correction angle = \frac{( angle\_bin \_index - N + 1 ) \times 2 π}{N} .$$

14. An apparatus for correcting a phase of a phase-modulated signal for blind demodulation, wherein the signal corresponds to constellation points plotted on a complex plane of a constellation diagram, the apparatus comprising:
a memory element operable to store data corresponding to a plurality of template signal model histograms, and a plurality of phase-modulated signal data points; and
a processor operable to
cross correlate a phase-modulated signal histogram with a corresponding template signal model histogram;
determine a correction angle from a maximum value of the cross correlation; and
multiply a phase angle of each constellation point by the correction angle.

15. The apparatus of claim 14, wherein the processor is further operable to:
divide the complex plane into a plurality of equally-spaced angle bins;
determine the phase angle of each constellation point;
determine the angle bin for each constellation point that corresponds to the phase angle for each constellation point; and
create a phase-modulated signal histogram of the number of points in each angle bin.

16. The apparatus of claim 14, wherein the processor is further operable to:
perform a discrete time Fourier transform of the phase-modulated signal histogram;
perform a discrete time Fourier transform of the template signal histogram;
multiply the discrete time Fourier transform of the template signal histogram by a complex conjugate of discrete time Fourier transform of the phase-modulated signal histogram; and
perform an inverse discrete time Fourier transform of the product of the discrete time Fourier transform of the template signal histogram and the complex conjugate of discrete time Fourier transform of the phase-modulated signal histogram.

17. The apparatus of claim 14, wherein the processor is further operable to:
determine an angle bin index of a maximum cross correlation value, wherein there are N angle bins; and
$$calculating the correction angle = \frac{( angle\_bin \_index - N + 1 ) \times 2 π}{N} .$$
